(19) United States
(12) Patent Application Publication
(10) Pub. No.: US 2025/0226239 A1
(43) Pub. Date: Jul. 10, 2025

(54) GAS BOX AND SEMICONDUCTOR MANUFACTURING APPARATUS

(71) Applicant: Tokyo Electron Limited, Tokyo (JP)

(72) Inventor: Masami SAKURAI, Tokyo (JP)

(21) Appl. No.: 19/000,972

(22) Filed: Dec. 24, 2024

(30) Foreign Application Priority Data
Jan. 5, 2024 (JP) 2024-000676

(51) Int. Cl. H01L 21/67

(52) U.S. Cl. CPC H01L 21/67017

(57) ABSTRACT

A gas box includes: a first housing having a flow path for a fluid provided therein; a valve equipped with a rotator and configured to open or close the flow path with rotation of the rotator; a first opening provided in a first wall of the first housing; a coupling mechanism including an elastic body and a first engaging portion engaged with the rotator to connect the rotator and the first wall, the coupling mechanism being provided to face the first opening so as to rotate together with the rotator by torque applied from outside the first housing; and a first seal included in the coupling mechanism and configured to be biased from the first engaging portion toward the first wall by the elastic body to seal the first opening.

### CROSS-REFERENCE TO RELATED APPLICATION

This application is based upon and claims the benefit of priority from Japanese Patent Application No. 2024-000676, filed on Jan. 5, 2024, the entire contents of which are incorporated herein by reference.

### TECHNICAL FIELD

The present disclosure relates to a gas box and a semiconductor manufacturing apparatus.

### BACKGROUND

For example, in a semiconductor manufacturing apparatus which performs substrate processing, an operation of supplying a gas to a processing container to perform the substrate processing. The gas used for the substrate processing is supplied into the processing container via a flow path from, for example, a gas box equipped with a gas line and an opening/closing valve.

Patent Document 1 discloses a configuration that improves safety of a gas box which accommodates a gas line including a manual opening/closing valve and an automatic opening/closing valve.

In the configuration disclosed in Patent Document 1, an internal space of the gas box is divided into an operation chamber and a non-operation chamber by a partition. The automatic opening/closing valve is accommodated in the non-operation chamber. The manual opening/closing valve has a main body portion accommodated in the non-operation chamber and an operation portion accommodated in the operation chamber. The non-operation chamber has a function of discharging an internal atmosphere thereof. For example, even if a gas leaks from the manual opening/closing valve, the non-operation chamber may discharge the gas, ensuring high operation safety of the manual opening/closing valve. In addition, the operation chamber has an opening which is opened or closed by a detachable lid. The lid may be separated independently from the non-operation chamber so that the operation portion of the manual opening/closing valve is operable.

### PRIOR ART DOCUMENT

### Patent Document

Patent Document 1: Japanese Laid-Open Patent Publication No. 2020-098854

### SUMMARY

According to one embodiment of the present disclosure, a gas box includes: a first housing having a flow path for a fluid provided therein; a valve equipped with a rotator and configured to open or close the flow path with rotation of the rotator; a first opening provided in a first wall of the first housing; a coupling mechanism including an elastic body and a first engaging portion engaged with the rotator to connect the rotator and the first wall, the coupling mechanism being provided to face the first opening so as to rotate together with the rotator by torque applied from outside the first housing; and a first seal included in the coupling mechanism and configured to be biased from the first engaging portion toward the first wall by the elastic body to seal the first opening.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a longitudinal cross-sectional view illustrating a semiconductor manufacturing apparatus including a gas box according to one embodiment.

FIG. 2 is a plan view illustrating a configuration example of the gas box.

FIG. 3 is a longitudinal cross-sectional view illustrating a configuration example of a tank provided in the gas box.

FIG. 4 is a perspective view illustrating a portion of a gas box according to a first embodiment.

FIG. 5 is a longitudinal cross-sectional view illustrating a portion of the gas box according to the first embodiment.

FIG. 6 is a longitudinal cross-sectional view illustrating a portion of the gas box according to the first embodiment.

FIG. 7 is a longitudinal cross-sectional view illustrating a portion of the gas box according to the first embodiment.

FIG. 8 is a perspective view illustrating a configuration example of a first wall and a coupling mechanism.

FIG. 9 is a perspective view illustrating the configuration example of the first wall and the coupling mechanism.

FIG. 10 is a longitudinal cross-sectional view illustrating a configuration example of a first engaging portion and a first seal.

FIG. 11 is a longitudinal cross-sectional view illustrating the configuration example of the first engaging portion and the first seal.

FIG. 12 is a longitudinal cross-sectional view illustrating a configuration example of the first engaging portion and a first recess.

FIG. 13 is a rear view illustrating a portion of a second wall.

FIG. 14 is a rear view illustrating a portion of the second wall.

FIG. 15 is an explanatory diagram illustrating a first through-hole and a second through-hole.

FIG. 16 is a plan view illustrating a configuration example of the gas box.

FIG. 17 is a plan view illustrating an assembly example of the gas box.

FIG. 18 is a plan view illustrating the assembly example of the gas box.

FIG. 19 is a plan view illustrating the assembly example of the gas box.

FIG. 20 is a plan view illustrating the assembly example of the gas box.

FIG. 21 is a plan view illustrating a configuration example of the first engaging portion and the first recess.

FIG. 22 is a plan view illustrating the configuration example of the first engaging portion and the first recess.

FIG. 23 is a plan view illustrating Comparative Example of a gas box.

FIG. 24 is a longitudinal cross-sectional view illustrating a portion of a gas box according to a second embodiment.

FIG. 25 is a longitudinal cross-sectional view illustrating a portion of a gas box according to a third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Semiconductor Manufacturing Apparatus

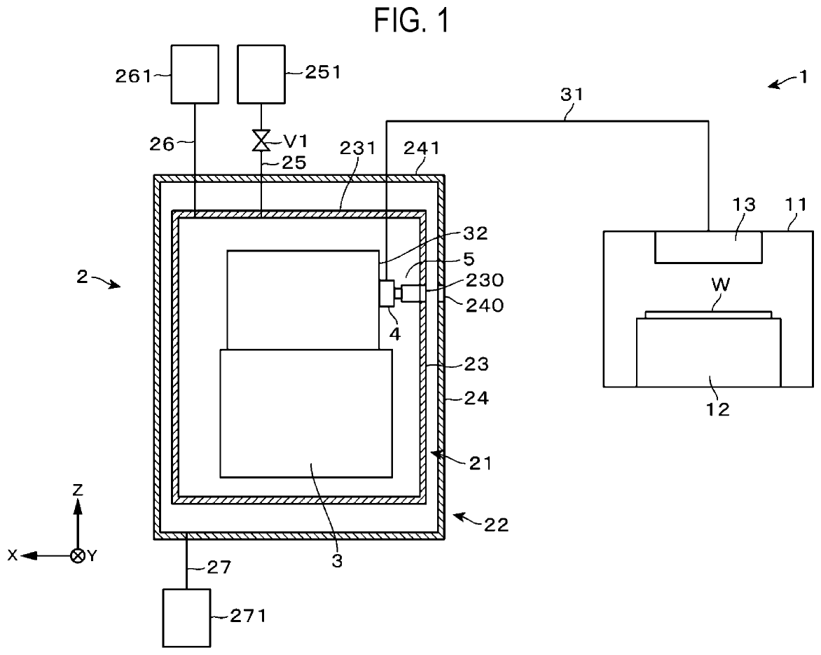

Hereinafter, a gas box 2 according to a first embodiment of the present disclosure will be described. FIG. 1 is a simplified longitudinal-sectional side view illustrating a semiconductor manufacturing apparatus 1 including the gas box 2.

As illustrated in FIG. 1, the semiconductor manufacturing apparatus 1 includes a processing container 11 which accommodates and processes a semiconductor wafer (hereinafter referred to as “wafer”) W, which is a substrate for semiconductor manufacture. A stage 12 on which the wafer W is placed is provided in an interior of the processing container 11.

A shower head 13 is arranged in a region facing the stage 12 in the interior of the processing container 11. The shower head 13 is configured to discharge a first gas for processing supplied from the gas box 2 via a flow path 31 toward the wafer W placed on the stage 12 in a shower-like manner.

With this configuration, the wafer W is subjected to a predetermined processing by the first gas in the interior of the processing container 11. Examples of the processing on the wafer W may include etching, film formation, ashing, and the like.

### First Embodiment of Gas Box

Next, a configuration example of the gas box 2 will be described with reference to the drawings.

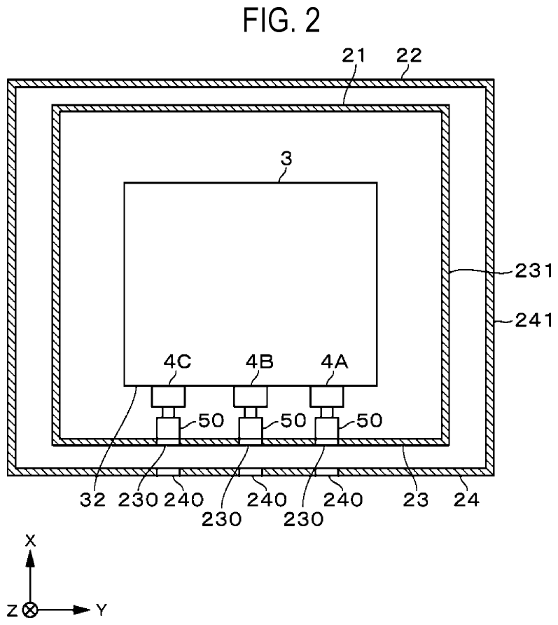

As illustrated in FIGS. 1 and 2, the gas box 2 includes a tank 3 which stores a liquid, which is a raw material for the first gas, a first housing 21 provided to surround the tank 3, and a second housing 22 provided to surround the first housing 21. In the following description of the gas box 2, a frond-rear direction will be referred to as an “X direction”, a left-right direction that horizontally intersects the front-rear direction will be referred to as a “Y direction”, and an up-down direction will be referred to as a “Z direction”.

The tank 3 is provided with a gas flow path 31 and a valve 4 which opens or closes the flow path 31. The valve 4 is configured to be opened or closed from the outside of the second housing 22. As illustrated in FIG. 2, each of the tank 3, the first housing 21, and the second housing 22 is configured to have, for example, a rectangular shape in a plan view. As illustrated in these drawings, the valve 4 is provided on a sidewall 32 of the tank 3. A wall of the first housing 21 facing the sidewall 32 will be referred to as a first wall 23, and a wall of the second housing 22 facing the first wall will be referred to as a second wall 24.

The first wall 23 and the second wall 24 are arranged to face each other with a gap provided therebetween in the front-rear direction. A portion of the first housing 21 other than the first wall 23 will be referred to as a first housing main body 231, and a portion of the second housing 22 other than the second wall 24 will be referred to as a second housing main body 241. The first housing main body 231 and the second housing main body 241 are laterally-opened boxes. The first wall 23 and the second wall 24 are detachably attached to the first housing main body 231 and the second housing main body 241 by, for example, screws (not illustrated), and block openings of the aforementioned boxes when mounted.

In order to open one sides of the first housing 21 and the second housing 22 so that the tank 3 and piping are accommodated in the first housing 21 or maintenance therefor is performed, as described above, the first wall 23 and the second wall 24 may be detached from the first housing main body 231 and the second housing main body 241, respectively. The first wall 23 and the second wall 24 are screwed to the first housing main body 231 and the second housing main body 241, respectively. Thus, the first wall 23 and the second wall 24 are in a mutually-determined positional relationship. In the following description, in terms of the front-rear direction (X-direction), a side of the tank 3 will be referred to as a front side, and a side of the second wall 24 will be referred to as a rear side.

The first housing 21 is connected to a source 251 of an inert gas such as a nitrogen (N₂) gas via a supply path 25 equipped with a valve V1, and is also connected to an exhaust mechanism 261, which includes an exhaust pump and a valve, via a first exhaust path 26. Thus, the N₂ gas is supplied to or exhausted from the interior of the first housing 21 so that the interior is kept at a preset pressure.

Further, the second housing 22 is connected to an exhaust line of a factory where the semiconductor manufacturing apparatus 1 is installed, or an exhaust mechanism 271 including an exhaust pump and a valve via a second exhaust path 27. Thus, the interior of the second housing 22, that is, a space between the first housing 21 and the second housing 22, is exhausted so that the interior of the second housing 22 is kept at a pressure (negative pressure) lower than the internal pressure of the first housing 21.

The interior of the first housing 21 is filled with the N₂ gas. Thus, a concentration of oxygen (O₂) in the interior of the first housing 21 is low. Therefore, as described later, in a case in which a gas generated inside the tank 3 reacts with an ambient air like an autogenous ignition material, even if the gas leaks from the tank 3 or the valve 4, ignition in the interior of the first housing 21 is prevented. Further, even if the leakage of the gas occurs, the gas is exhausted together with the N₂ gas. This enhances safety.

Meanwhile, the first wall 23 is screwed to the first housing main body 231. Thus, a slight gap is formed at a connection point between the first wall 23 and the first housing main body 231. Therefore, a portion of the N₂ gas in the first housing 21 enters the second housing 22 set to the negative pressure. The gas is quickly exhausted out of the second housing 22 via the second exhaust path 27, which prevents the leakage of the gas outward of the gas box 2.

### Tank

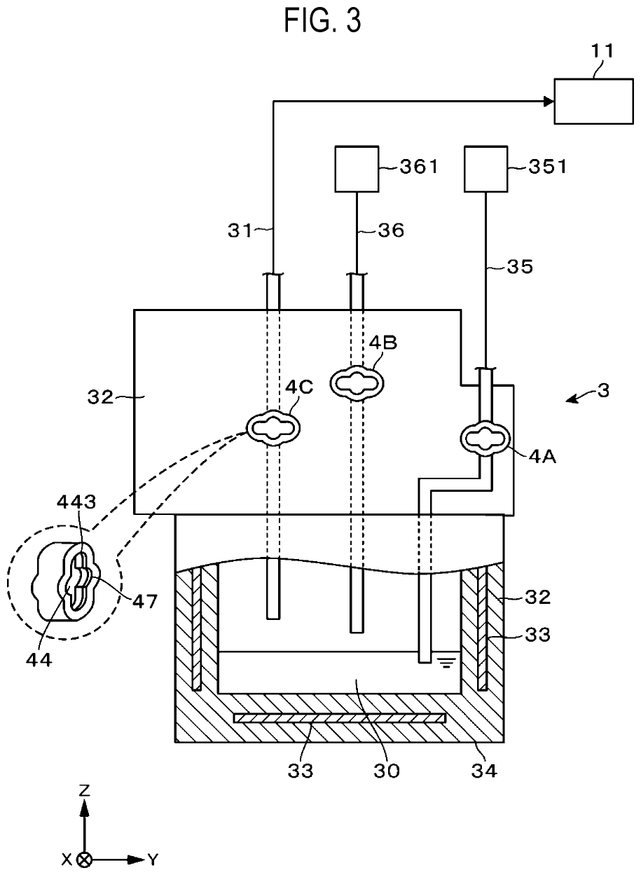

As illustrated in FIG. 3, the tank 3 stores a liquid 30, which is, for example, a gas raw material, and includes a heater 33 to heat the liquid 30. For example, the heater 33 is embedded in the sidewall 32 or a bottom wall 34 of the tank 3. The heated liquid 30 gradually vaporizes with the supply of a carrier gas (an inert gas to be described later) to generate the first gas. In this example, the first gas is supplied to the processing container 11 together with the carrier gas.

To do this, the tank 3 is connected to a first flow path 35 for supplying the liquid 30 to the tank 3, a second flow path 36 for supplying the carrier gas to the tank 3, and a third flow path 31 for supplying the first gas and the carrier gas from the tank 3 to the processing container 11. These first to third flow paths 35, 36 and 31 correspond to flow paths for a fluid that will become a gas. Upstream sides of both the first and second flow paths 35 and 36 are connected to a reservoir 351 for the liquid 30 and a source 361 for the carrier gas such as argon (Ar) gas, respectively, while a downstream side of the third flow path 31 is connected to the shower head 13 in the processing container 11.

Further, as illustrated in FIGS. 1 to 3, valves 4A, 4B and 4C are arranged in the first to third flow paths 35, 36 and 31, respectively, to open or close the respective flow paths. As illustrated in FIG. 2, the valves 4A, 4B and 4C are all provided on the sidewall 32 of the tank 3 facing the first wall 23. Since the valves 4A, 4B and 4C have the same configuration, descriptions herein will focus on the valve 4C provided in the third flow path 31 by way of example. Hereafter, the valve 4C may be referred to as the “valve 4” and the third flow path 31 may be referred to as the “flow path 31”.

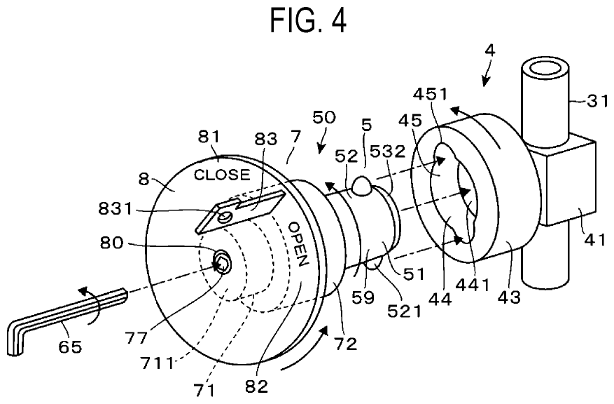

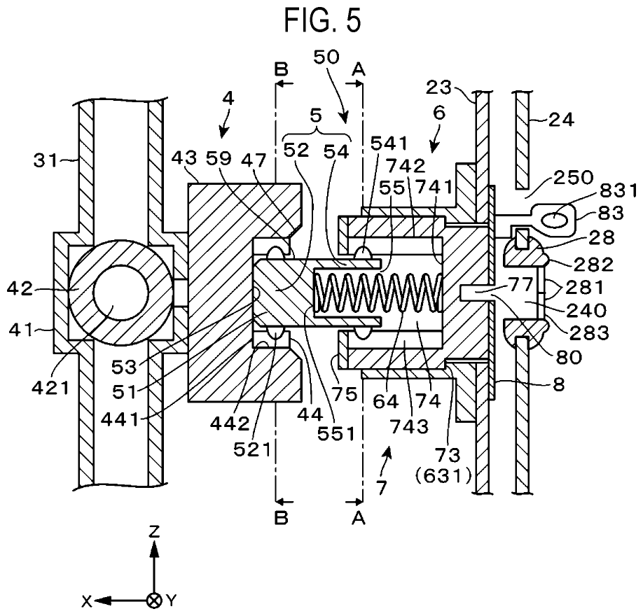

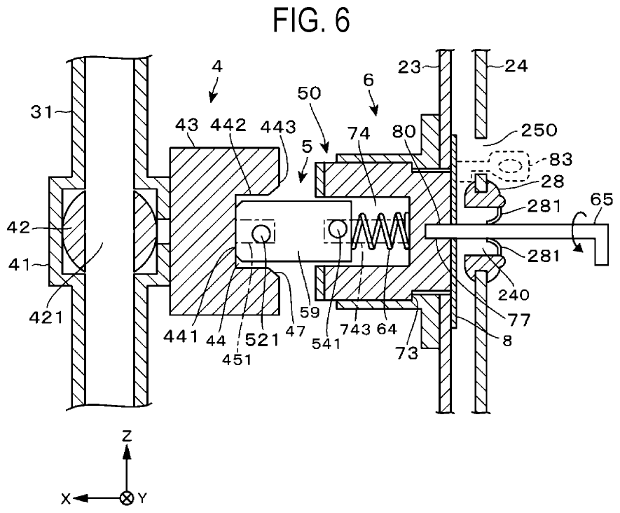

As illustrated in FIGS. 4 to 6, the valve 4 is configured by, for example, a ball valve such that a ball 42 provided in a main body 41 rotates around a horizontal rotation axis with rotation of a rotator 43 to open and close the flow path 31. In addition, the rotation of the rotator 43 is in the same rotation direction as the ball 42. The ball 42 has an opening 421 formed in the center thereof, and is set such that, as illustrated in FIGS. 4 and 5, the opening 421 does not correspond to the flow path 31 and the outer surface of the ball 42 blocks the flow path 31 when the valve 4 is in a closed state. Further, the ball 42 is set such that the opening 421 is connected to the flow path 31 at a position where the valve opens the flow path 31, as illustrated in FIG. 6.

The rotator 43 in this example has a first recess 44 which opens toward the first wall 23. The first recess 44 has a flat bottom surface 441 extending in the up-down direction (Z-direction) and a side surface 442 extending in the opening direction. A rotational center of the first recess 44 is formed to be aligned with a rotational center of the rotator 43. Further, a tip side (X-direction rear side) of the side surface 442 of the first recess 44 in the opening direction forms an opening edge 443 of the first recess 44 (see FIG. 6). The opening direction refers to a depth direction of the first recess 44 opposite to the bottom surface 441 of the first recess 44 and corresponds to the X-direction in the example illustrated in FIG. 5. The first recess 44 is configured to rotate by virtue of torque applied from the outside of the second housing 22 via a coupling mechanism 50 to be described later. Therefore, a shape of the first recess 44 will be described together with the coupling mechanism 50.

### Coupling Mechanism

Next, the coupling mechanism 50 will be described with reference to FIGS. 4 to 11. The coupling mechanism 50 includes a first engaging portion 5, an elastic body 64, and a first seal 7. First, an outline of the coupling mechanism 50 will be described with reference to FIG. 4, which is a perspective view.

The coupling mechanism 50 is in a state of entering and being engaged with the first recess 44 and being exposed to the outside of the first housing 21 via a first opening 230 (to be described later) in the first wall 23, so that an operator may rotate the rotator 43 of the valve 4 from the outside of the second housing 22.

The coupling mechanism 50 is configured to rotate when the operator applies the torque via the first opening 230 by using a jig (hex wrench 65) introduced into the second housing 22 from the outside of the second housing 22. As a result, the rotator 43 of the valve 4 may also be rotated.

As described above, it is necessary to prevent the leakage of the gas from the interior of the first housing 21. Thus, the coupling mechanism 50 has a structure to seal the aforementioned first opening 230 in the first wall 23 and hermetically seal the interior of the first housing 21. Accordingly, the coupling mechanism 50 is provided inside the first housing 21 to connect the rotator 43 of the valve 4 and the first wall 23.

Further, as will be described in detail later, when attaching the first wall 23 to the first housing main body 231 for the assembly of the first housing 21, the coupling mechanism 50 provided on the first wall 23 is inserted into the first recess 44 in the rotator 43 of the valve 4, thereby implementing the aforementioned engagement. At this time, in order to implement the engagement even if there is a misalignment of the tank 3 (that is, a misalignment of the first recess 44) in the interior of the first housing main body 231, the coupling mechanism 50 is configured to have a swingable tip end (first engaging portion 5) for implementing the engagement.

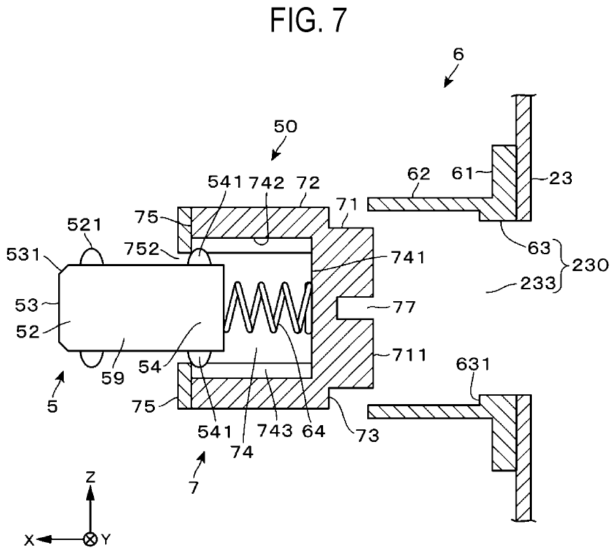

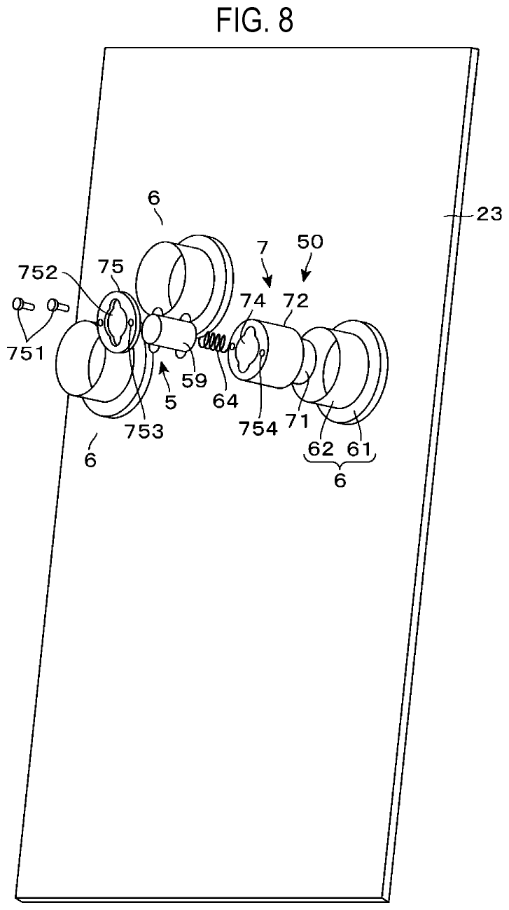

To provide a more detailed description of the coupling mechanism 50, additional description on the first wall 23 of the first housing will be made. As illustrated in FIGS. 7 and 8, an outer frame 6, which rotatably surrounds the coupling mechanism 50, is connected to the first wall 23. The outer frame 6 is made of, for example, a resin to secure the aforementioned sealing property. The outer frame 6 has an annular flange portion 61 connected to the first wall 23, and a cylindrical portion 62 formed to protrude horizontally inward of the first wall 23 (to the front side).

A base side (the side of the first wall 23) of the cylindrical portion 62 is configured as an annular portion 63 which protrudes inward of the outer frame 6. A tip of the annular portion 63 is formed as an annular surface 631.

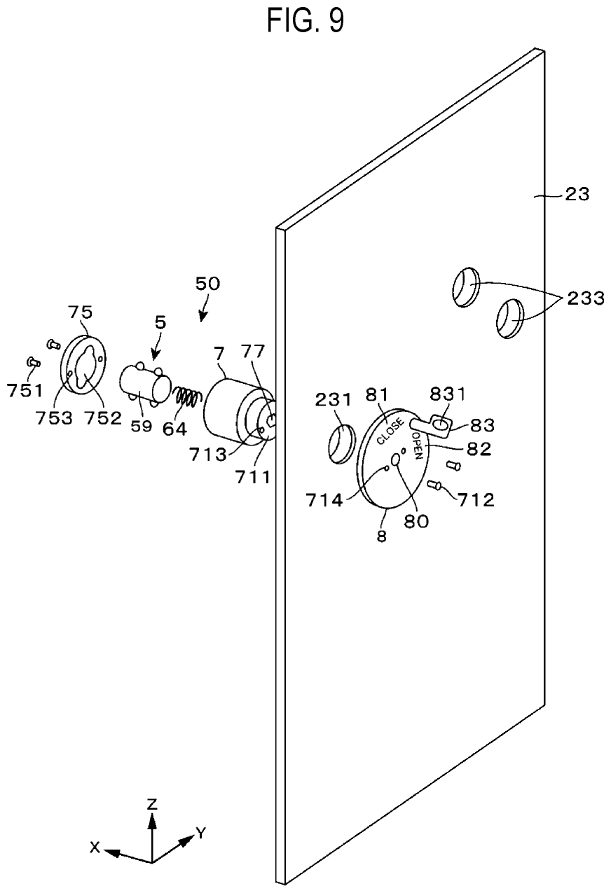

Further, as illustrated in FIGS. 7 and 9, a through-hole 233 is provided in the first wall 23. In this example, when the outer frame 6 is connected to the first wall 23, a peripheral surface of the through-hole 233 and an inner surface of the annular portion 63 are continuous with each other. An opening defined by the through-hole 233 and the annular portion 63 forms the first opening 230.

Next, the first seal 7 constituting the coupling mechanism 50 will be described. The first seal 7 functions to block the first opening 230. As illustrated in FIGS. 4 to 9, the first seal 7 is configured as a combination of a cylindrical portion 71 rotatably fitted into the outer frame 6, and a cylindrical portion 72 provided on the front side of the columnar portion 71. The columnar portion 71 is fitted into the first opening 230 to create a slight gap between the annular portion 63 and the columnar portion 71.

The cylindrical portion 72 is formed in a circular shape when viewed from the front side (the side of the tank 3), with a diameter larger than that of the columnar portion 71. A central axis of the columnar portion 71 is positioned on the extension of the central axis of the cylindrical portion 72. Thus, a connection portion between the columnar portion 71 and the cylindrical portion 72 forms a stepped portion. A surface formed by the stepped portion is aligned with the surface 631 at the tip of the annular portion 63 to form an annular sealing surface 73 which is brought into contact with the surface 631.

Further, the cylindrical portion 72 has a second recess 74 which opens toward the front side. The second recess 74 has a flat bottom surface 741 on a Y-Z plane and a side surface 742 extending in the opening direction. The first engaging portion 5 is located in the second recess 74 via the elastic body 64. The opening direction (depth direction) of the second recess 74 is the X-direction in the example illustrated in FIGS. 5 to 7.

As illustrated in FIGS. 4 to 9, the first engaging portion 5 includes a columnar member 59 which extends linearly in the front-rear direction (the X-direction) and a total of four protrusions 521 and 541 provided on the columnar member 59. The tip of the first engaging portion 5 constitutes an entry portion 51 which enters the first recess 44 in the rotator 43 of the valve 4 to be engaged with the first recess 44. The entry portion 51 in this example has a front portion (a first linear portion extending in a straight shape) 52 of the aforementioned columnar member 59 and two first protrusions 521. Further, when the engagement is implemented, a tip 53 (constitutes a flat surface) of the columnar member 59 is in contact with the bottom surface 441 of the first recess 44.

Each of the first protrusions 521 protrudes from the side surface of the columnar member 59 in a direction orthogonal to the extension direction (the X-direction) of the columnar member 59. In other words, the first protrusions 521 are provided to protrude in the direction intersecting the extension direction of the first linear portion (the front portion 52 of the columnar member 59). The first protrusions 521 are spaced apart by 180 degrees from each other around the columnar member 59, and are provided at the same position in an axial direction of the columnar member 59. More specifically, each first protrusion 521 is positioned slightly closer to the base rather than the tip 53 of the columnar member 59.

Further, each first protrusion 521 is circular when viewed in the protruding direction, and has a diameter that is reduced toward the protruded end. Each first protrusion 521 has a roughly semicircular shape in a side view. Due to such a shape and the first engaging portion 5 having a swingable configuration, the assembly of the first housing 21 may easily be implemented. During the assembly of the first housing 21, even if the first protrusion 521 collides with the opening edge 443 of the first recess 44 while the entry portion 51 is introduced into and engaged with the first recess 44 in the rotator 43 of the valve 4, the first protrusion 521 slides along the opening edge 443 and enters the first recess 44 without being caught. Thus, the first protrusion 521 is shaped to make the assembly of the first housing 21 easier.

The tip of the columnar member 59 ahead of the first protrusion 521 is tapered toward the tip 53 of the columnar member 59. Thus, the side peripheral surface at the tip end of the columnar member 59 constitutes an inclined surface 531 which is inclined with respect to the extension direction (the X-direction) of the columnar member 59. The inclined surface 531 is coplanar with the flat surface constituted by the tip 53 of the columnar member 59.

The provision of the inclined surface 531 contributes to make the assembly of the first housing 21 easier. Specifically, even if the columnar member 59 is brought into contact with the opening edge 443 of the first recess 44 in the valve 4 during the assembly, the inclined surface 531 may slide along the opening edge 443 so that the columnar member 59 enters the first recess 44.

Further, a rear portion (second linear portion extending in a straight shape) 54 of the columnar member 59 is a region that is accommodated in the second recess 74 of the cylindrical portion 72. In this region, two second protrusions 541 are formed to protrude from the side surface of the columnar member 59 in the direction orthogonal to the extension direction of the columnar member 59. In other words, the second protrusions 541 are provided to protrude in the direction intersecting the extension direction of the second linear portion (the rear portion 54 of the columnar member 59). These second protrusions 541 are spaced apart by 180 degrees from each other around the columnar member 59, and are provided at the same position in the axial direction of the columnar member 59. More specifically, each second protrusion 541 is positioned slightly closer to the tip rather than the base of the first engaging portion 5.

The second protrusion 541 has the same shape as the first protrusion 521. As will be described later, the second protrusion 541 swings inside a groove 743 (to be described later) continuous with the second recess 74 with the swinging of the tip of the columnar member 59. However, the above-described shape of the second protrusion 541 reduces resistance when it is brought into contact with the wall of the groove 743. This ensures smooth swinging. In addition, as illustrated in FIG. 6, in this example, the second protrusion 541 is slightly circumferentially misaligned from the first protrusion 521 when viewed in the axial direction of the columnar member 59. However, the first and second protrusions may be positioned to approximately overlap each other.

Further, as illustrated in FIG. 5, a third recess 55 is formed in the rear portion 54 of the columnar member 59. An opening direction (depth direction) of the third recess 55 is aligned with the extension direction of the columnar member 59. The third recess 55 is located inside the second recess 74 to open toward the bottom surface 741 of the second recess 74. Further, a bottom surface 551 of the third recess 55 is formed to face the bottom surface 741 of the second recess 74.

The elastic body 64 is provided between the third recess 55 and the second recess 74. The elastic body 64 is, for example, a spring that expands and contracts in the front-rear direction, and has both ends arranged to come into contact the bottom surface 551 of the third recess 55 and the bottom surface 741 of the second recess 74, respectively. The elastic body 64 is configured to be surrounded by a side surface of the third recess 55, which prevents any a misalignment between the elastic body 64 and the columnar member 59. More specifically, this configuration prevents the elastic body 64 from being deviated from the columnar member 59 (the elastic body 64 from being not positioned in the extension direction of the columnar member 59) due to such a misalignment. This ensures a sealing effect using the elastic body 64.

The following returns to describing the first seal 7. The second recess 74 is formed in a circular shape when viewed from the side of the tank 3 to accommodate the columnar member 59. Further, the groove 743 corresponding to the second protrusion 541 of the first engaging portion 5 is formed in the side surface 742 of the second recess 74, so that the second protrusion 541 of the first engaging portion 5 enters the groove 743. Accordingly, in the second recess 74, two grooves 743 are provided at two positions corresponding to the two second protrusions 541. These grooves 743 are formed to extend from an opening to the bottom surface 741 of the second recess 74 along the opening direction of the second recess 74 and face each other with the center of that second recess 74 therebetween.

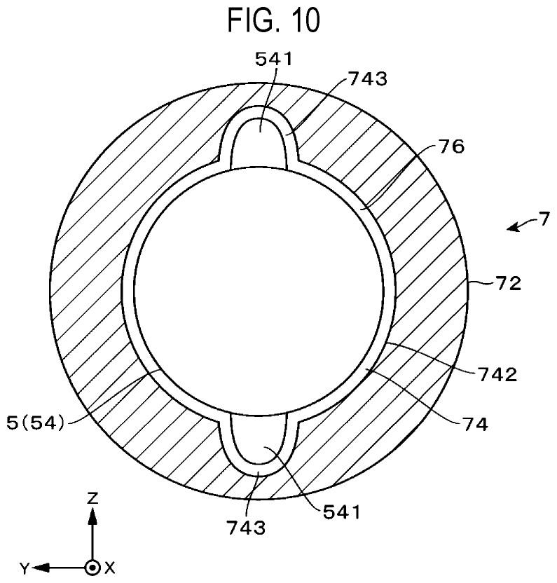

A relationship between the second recess 74 and the rear portion 54 of the columnar member 59 in the first engaging portion 5 is illustrated in FIG. 10. FIG. 10 is a longitudinal cross-sectional view taken along line A-A in FIG. 5 as viewed from the side of the tank 3. As illustrated, the side surface 742 of the second recess 74 is formed to cover the rear portion 54 and the second protrusion 541 of the columnar member 59 with a gap 76 provided therebetween. The gap 76 is set to have almost the same size along the periphery of the rear portion 54, for example, when the rotation axes of the columnar member 59 and the second recess 74 are aligned with each other.

As described above, the first engaging portion 5 is located in the second recess 74 of the first seal 7 via the elastic body 64. In this case, the first engaging portion 5 is set such that the elastic body 64 applies pressure to the first engaging portion 5. Therefore, a regulation plate 75 is attached to the tip of the first seal 7 by a screw 751. As illustrated in FIGS. 8 and 9, the regulation plate 75 has an opening 752 shaped to correspond to the columnar member 59 and the respective protrusions (the first and second protrusions 521 and 541).

When attaching the regulation plate 75 to the first seal 7, the front portion (the first linear portion) 52 and the first protrusion 521 of the columnar member 59 are passed through the opening 752 to protrude forward of the regulation plate 75. Then, the regulation plate 75 is rotated relative to the columnar member 59, and is fixed to the first seal 7 by the screw 751 at a position where the second protrusion 541 is not passed through the opening 752. In other words, the regulation plate 75 is fixed to the first seal 7 so as to block the front end of the groove 743 formed in the first seal 7. In FIGS. 8 and 9, reference numerals 753 and 754 indicate screw holes formed in the regulation plate 75 and the first seal 7, respectively.

In a state in which the first engaging portion 5 does not yet enter the first recess 44 of the valve 4 and is not engaged with the first recess 44, the first engaging portion 5 may apply pressure toward the front side by the elastic body 64 inside the first seal 7, and the second protrusion 541 is brought into contact with the regulation plate 75 (see FIG. 7). This prevents the first engaging portion 5 from being deviated from the first seal 7 to the front side. In addition, when the first engaging portion 5 is pressurized toward the read side to resist a biasing force of the elastic body 64, the rear end (base) of the first engaging portion 5 may be moved toward the bottom surface 741 of the second recess 74 in the first seal 7.

Further, a second engaging portion 77 is formed on the first seal 7 to be exposed to the first opening 230. The second engaging portion 77 is used when being engaged with a jig that applies torque from the outside of the first housing 21, such as the hex wrench 65. In this example, as illustrated in FIGS. 6, 7 and 9, the second engaging portion 77 is formed as a recess in the center of a bottom surface 711 of the columnar portion 71 to be opened toward the first opening 230. The hex wrench 65 is inserted into the recess.

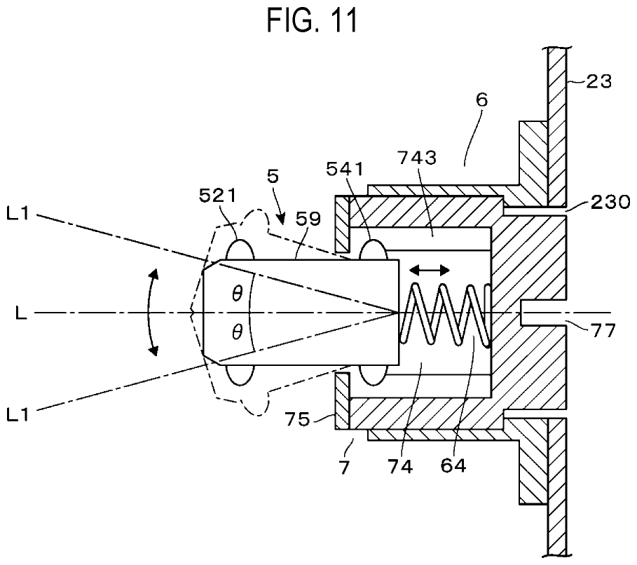

The first engaging portion 5 described above is accommodated in the first seal 7 via the gap 76. The base of the first engaging portion 5 is supported by the elastic body 64. Therefore, as illustrated in FIG. 11, in a state in which the engagement between the first engaging portion 5 and the rotator 43 is not yet implemented, when force is applied to the first engaging portion 5, the tip of the first engaging portion 5 may swing with respect to the base thereof. Such a swing may be performed not only in the up-down direction illustrated in the diagram but also in all directions of 360 degrees including the left-right direction and the diagonal direction.

Further, as will be described later, the range of the swing is set to absorb the misalignment of the tank 3 inside the first housing 21. A central axis L of the second recess 74 in the first seal 7 is illustrated in FIG. 11. A central axis of the columnar member 59 with the greatest inclination with respect to the central axis L is denoted by reference numeral L1. The gap 76 between the first engaging portion 5 and the first seal 7 is formed such that an inclination θ between the central axes L and L1 is equal to or greater than, for example, 10 degrees.

### Valve

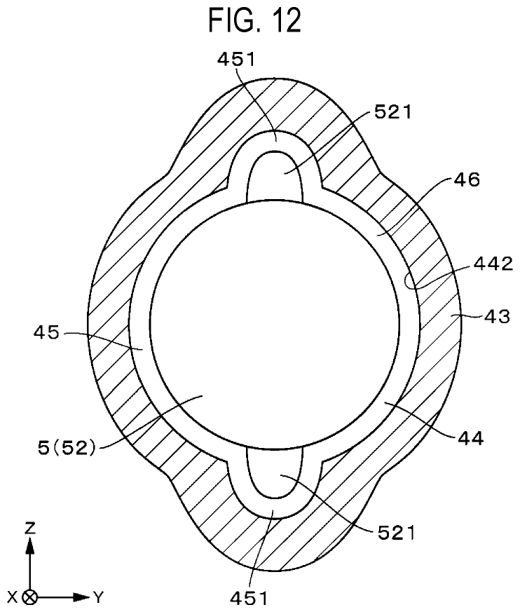

Returning to the description of the valve 4, the shape of the first recess 44 provided in the valve 4 will be described with reference to FIGS. 4 and 12. FIG. 12 is a longitudinal cross-sectional view taken along line B-B in FIG. 5 as viewed from the first wall 23. As described above, the first recess 44 has the bottom surface 441 and the side surface 442. Further, in conformity to the shape of the first engaging portion 5, the first recess 44 has a main portion 45 to which the front portion 52 of the columnar member 59 enters and a sub-portion 451 to which the first protrusion 521 enters. The sub-portion 451 is formed to protrude from the main portion 45.

As described above, by forming the first protrusion 521 in the first engaging portion 5 and forming the sub-portion 451 in the first recess 44 in conformity to the shape of the first engaging portion 5, the first engaging portion 5 is engaged with the first recess 44 while being aligned in the circumferential direction.

Thus, as will be described later, the torque is applied to the first engaging portion 5 from the outside of the first housing 21 and subsequently, is transmitted to the first recess 44 with the rotation of the first engaging portion 5. As a result, the first recess 44 also rotates. With this configuration, the valve 4 may be switched between the closed state illustrated in FIG. 5 and the open state illustrated in FIG. 6 with the rotation of the first recess 44.

Further, the region from the opening edge 443 of the side surface 442 of the first recess 44 toward the bottom surface 441 is defined as a inclined surface 47 which is inclined with respect to the opening direction of the first recess 44 (see FIGS. 5 and 6). The inclined surface 47 is formed such that the opening area of the first recess 44 increases from the bottom surface 441 of the first recess 44 toward the opening edge 443. In FIG. 4, the illustration of the inclined surface 47 is omitted.

Like the inclined surface 531 of the columnar member 59 in the first engaging portion 5, the inclined surface 47 plays a role of guiding the entry portion 51 of the first engaging portion 5 to the first recess 44 so that the entry portion 51 enters the first recess 44 for the assembly of the first housing 21. In other words, even if the edge of the entry portion 51 is brought into contact with the opening edge 443 of the first recess 44 during the assembly, the entry portion 51 may slide along the inclined surface 47 and enter inward of the first recess 44. This facilitates the assembly. In addition, the shapes of the inclined surface 47 of the first recess 44, and the shapes of the inclined surface 531 and the first protrusion 521 of the first engaging portion 5 have been described as facilitating the assembly of the first housing 21, but may also contribute to increase a tolerance for the misalignment of the tank 3.

When the entry portion 51 has entered the first recess 44, the gap 46 is formed between the main portion 45 and the columnar member 59 and between the sub-portion 451 and the first protrusion 521. Since such individual parts are designed to form the gap 46, the first engaging portion 5 is likely to enter the first recess 44. However, the gap 46 may be set to such an extent that the first protrusion 521 does not move from the sub-portion 451 to the main portion 45 during the rotation of the first engaging portion 5. Thus, the first recess 44 is configured to rotate with the rotation of the first engaging portion 5.

### Second Housing

Next, the second housing 22 will be described. The second wall 24 of the second housing 22, which faces the first wall 23, has a third opening 240 provided to face the first opening 230. The third opening 240 is formed such that the hex wrench 65 enters the second housing 22 from the outside of the second housing 22.

Further, a second seal 28 as an elastic body is provided in the third opening 240 to block and seal the third opening 240. The second seal 28 is configured to has a thick annular portion 282 formed along and is fixed to an entrance edge of the third opening 240, and a thin circular portion 283 surrounded by the annular portion 282. For example, a grommet may be used as the second seal 28.

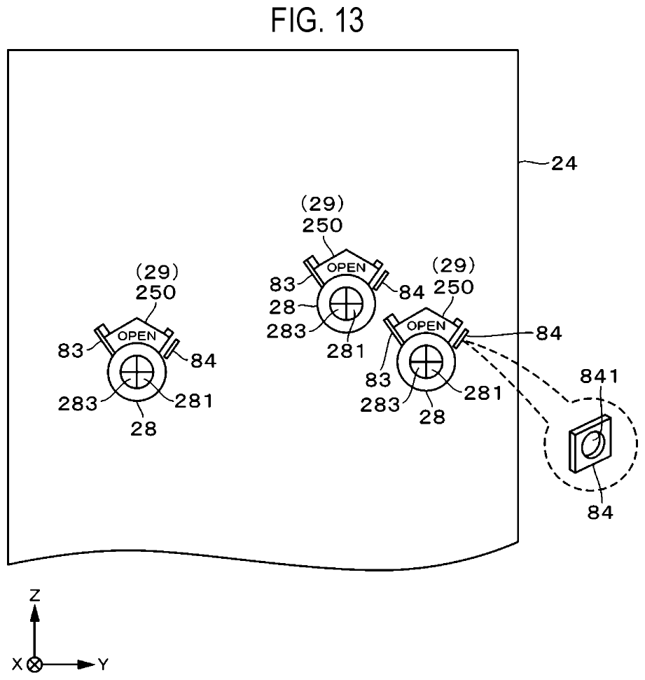

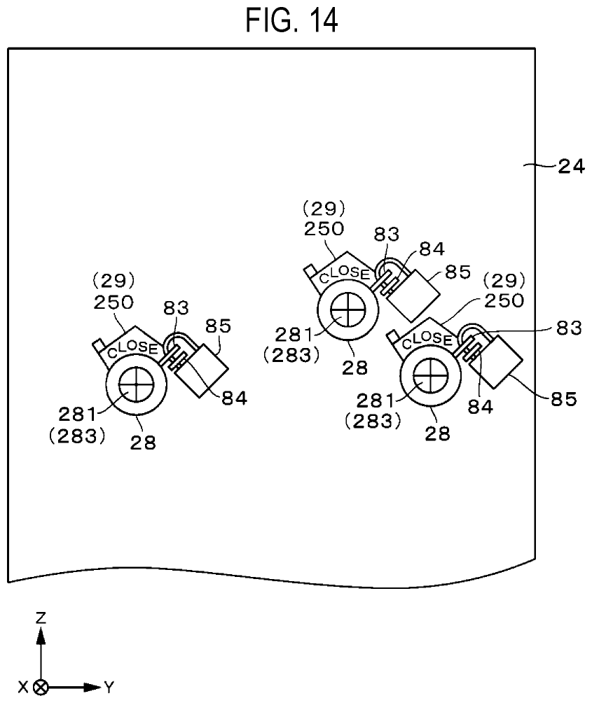

As illustrated in FIGS. 13 and 14, a plurality of slits is formed in the thin circular portion 283 of the second seal 28 to extend radially from the center of the thin circular portion 283. As a result, a plurality of fan-like sealing pieces 281 is formed along the periphery of the third opening 240. In these drawings, an example in which four sealing pieces 281 are provided by cutting the thin circular portion 283 in a cross shape is illustrated. As illustrated in FIG. 5, when the hex wrench 65 does not enter the third opening 240, the tips of the sealing pieces 281 come into contact with each other at the center of the third opening 240. Further, as illustrated in FIG. 6, when the hex wrench 65 enters the third opening 240, the tips of the sealing pieces 281 are spaced apart from each other and extend toward the first wall 23. In the state in which the hex wrench 65 is inserted, the individual sealing pieces 281 are brought into close contact with the hex wrench 65 due to the restoring force of the elastic body. This suppresses the sealing property of the interior of the second housing 22 from being reduced due to the insertion of the hex wrench 65.

Further, a window 29 is formed in the second wall 24 so as to visually check the interior of the second housing 22 therethrough from the outside. The window 29 is provided to indicate the open or closed state of the valve 4 outward of the second housing 22. In this example, a second opening 250 is formed as the window 29 in the second wall 24.

### Display

Returning to the description of the coupling mechanism 50, a display 8, which serves as a member to indicate the open or closed state of the valve 4, is connected to the coupling mechanism 50. The display 8 is configured to rotate together with the coupling mechanism 50. As illustrated in FIGS. 4 and 9, the display 8 is formed in a disk shape which is larger in size than the first opening 230. Further, the display 8 is attached to the bottom surface 711 of the first seal 7 by a screw 712 via the first opening 230 from the outside of the first wall 23. The center of the display 8 overlaps the center of the first seal 7. Accordingly, the display 8 is formed as a disk that rotates around a center axis thereof. In FIG. 9, reference numerals 713 and 714 indicate screw holes formed in the bottom surface 711 of the first seal 7 and the display 8, respectively. In addition, a through-hole 80 through which the hex wrench 65 passes is formed in a central region of the display 8. The recess 77 of the first seal 7 described above is exposed to the outside of the first housing 21 via the through-hole 80 (see FIG. 4).

As described above, the display 8 is formed as a disk which is larger in size than the first opening 230. Thus, the display 8 is provided from a region facing the first opening 230 of the first housing 21 to a region beyond the first opening 230, and serves as a deviation preventer for preventing the coupling mechanism 50 from being deviated from the first wall 23.

The display 8 has a first region 81 and a second region 82, which are circumferentially adjacent to each other on a rear surface of the display 8. More specifically, the rear surface is divided into four equal regions in a cross shape, and two adjacent regions among the four equal regions are referred to as the first region 81 and the second region 82. A region facing the window 29 switches between the first region 81 and the second region 82 with the rotation of the display 8 according to the opening or closing of the valve 4.

In this example, as distinct visual information, the first region 81 defined at the left side of the display 8 is marked with the text “CLOSE”, while the second region 82 defined at the right side of the display 8 is marked with the text “OPEN”. In this case, when the coupling mechanism 50 rotates to the right and the valve 4 is closed, the first region 81 overlaps the window 29 (the second opening 250) and “CLOSE” is displayed via the window 29. On the other hand, when the coupling mechanism 50 rotates to the left and the valve 4 is opened, the second region 82 overlaps the window 29 and “OPEN” is displayed via the window 29.

Further, a plate-like clamp 83 is provided between the first region 81 and the second region 82 of the display 8 to extend toward (that is, the rear side) the second wall 24 of the second housing 22. Therefore, the clamp 83 is connected to the first seal 7 of the coupling mechanism 50 via the display 8. The clamp 83 constitutes a first through-hole forming member. The clamp 83 is inserted into the second opening 250 of the second wall 24 so that the tip end of the clamp 83 is positioned outside the second housing 22. A first through-hole 831 is formed in the tip end of the clamp 83. As the first seal 7 rotates, the clamp 83 moves around the rotation axis of the first seal 7 so that the tip end of the clamp 83 with the first through-hole 831 moves outward of the second housing 22.

Meanwhile, as illustrated in FIGS. 13 and 14, a clamp 84 as a plate-like member is provided on the rear surface of the second wall 24 of the second housing 22 to extend backward from the second wall 24. Therefore, the clamp 84 is provided outside the second housing 22. The clamp 84 constitutes a second through-hole forming member with a second through-hole 841, and is positioned near one side of the second opening 250 in the left-right direction (the Y direction).

In this example, as illustrated in FIG. 14, in a first state in which the valve 4 is closed and “CLOSE” is displayed, the clamps 83 and 84 are close to each other and the first through-hole 831 is opened in an opening direction of the second through-hole 841. On the other hand, as illustrated in FIG. 13, in a second state in which the valve 4 is opened and “OPEN” is displayed, the clamps 83 and 84 are spaced apart significantly from each other unlike the first state. As described above, since the orientation of the first through-hole 831 is changed unlike that in the first state, the first through-hole 831 is not opened in the opening direction of the second through-hole 841.

In the first state, the clamps 83 and 84 have the above-described positional relationship. Thus, as illustrated in FIG. 14, a latch 851 of a padlock 85 is inserted into the first through-hole 831 and the second through-hole 841 to implement locking using the padlock 85. By installing the padlock 85 as described above and fixing a position of the clamp 83, the valve 4 is prevented from coming into the second state “OPEN” in which the valve 4 is opened. This ensures the safety.

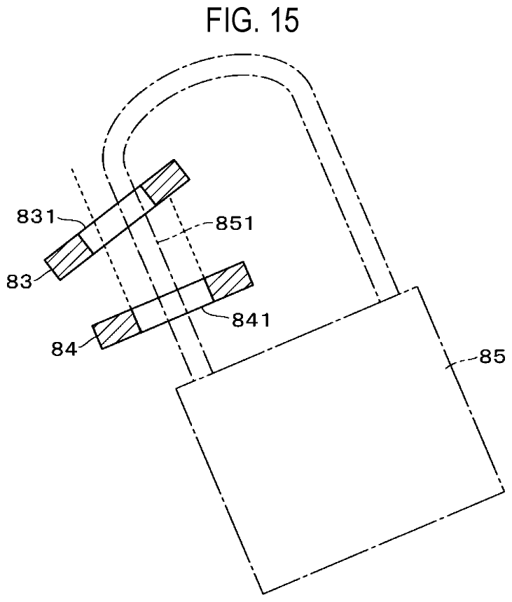

Further, in the state in which the first through-hole 831 is opened in the opening direction of the second through-hole 841, it is not necessary for the first through-hole 831 and the second through-hole 841 to completely face each other. For example, as illustrated in FIG. 15, the opening directions of the first through-hole 831 and the second through-hole 841 may not be aligned as long as the latch 851 of the padlock 85 can be inserted into the first through-hole 831 and the second through-hole 841 to implement locking. Further, instead of locking the padlock through the first through-hole 831 and the second through-hole 841, a string may be inserted between the first through-hole 831 and the second through-hole 841 to tie them together. This suppresses the rotation of the valve 4, which keeps the valve 4 in the closed state.

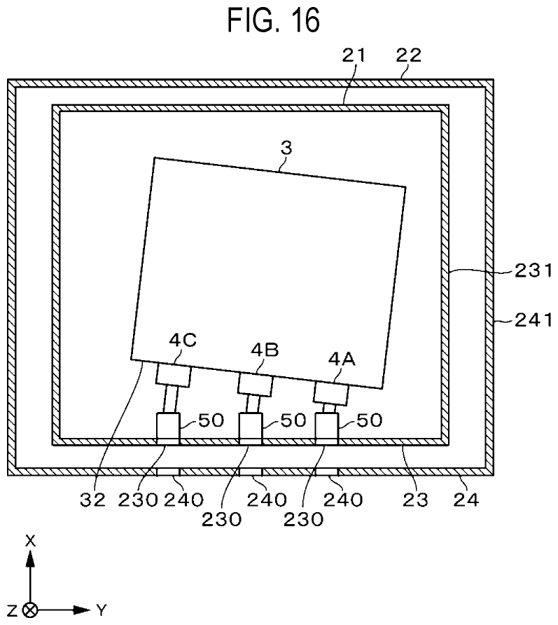

In this example, as illustrated in FIG. 16, three valves 4A, 4B and 4C are provided in the tank 3. Therefore, as illustrated in FIGS. 8 and 9, the through-holes 233 are formed in the first wall 23 and the second wall 24 at positions corresponding to the three valves 4A, 4B and 4C, and the second openings 250 and the third openings 240 are formed in the first wall 23 and the second wall 24, respectively. Further, the coupling mechanism 50, the outer frame 6, and the second through-hole forming member 84 are provided for the valves 4A, 4B and 4C.

Next, the assembly of the gas box 2 and the opening/closing operation of the valve 4 after the assembly will be described. The tank 3 and pipes (not illustrated) are accommodated in the interior of the first housing 21. According to variations during the installation of the pipes or the assembly, the tank 3 may not be arranged at a preset position. The gas box 2 in this case will be described by way of example.

FIG. 2 illustrates a state in which the tank 3 is arranged at a preset position in the interior of the first housing 21. FIG. 16 illustrates a state in which the tank 3 is arranged to be deviated from the preset position. In FIG. 16, the sidewall 32 of the tank 3 where the valves 4A to 4C are arranged to be inclined with respect to the first wall 23 rather than face the first wall 23. In practice, the tank 3 is misaligned by a few millimeters, but is exaggerated and depicted on a large scale in FIG. 16.

In the assembly of the gas box 2, first, the coupling mechanism 50 is attached to the first wall 23. Specifically, the coupling mechanism 50 is supported by each outer frame 6 at the inner side of the first wall 23 (at the side of the tank 3), while the display 8 is fixed to the first seal 7 by the screw 712 at the outer side of the first wall 23 (at the side of the second wall 24). Further, after the tank 3 is accommodated in the first housing main body 231, the first wall 23 is attached to the first housing main body 231.

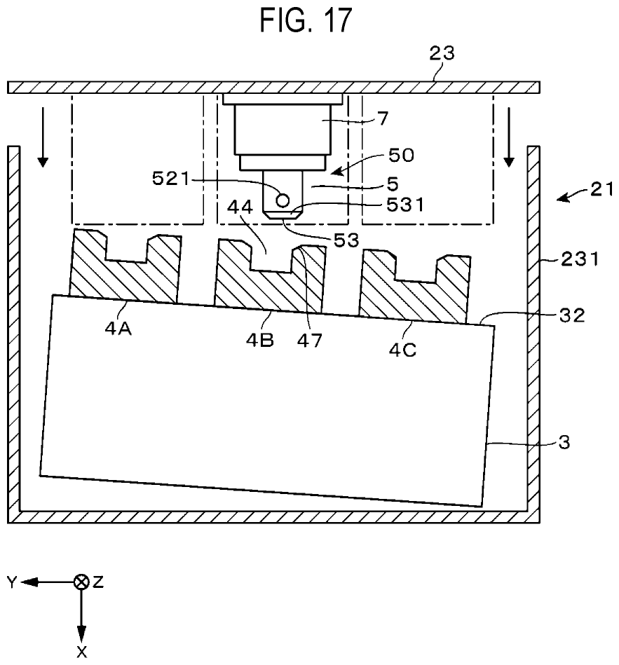

FIGS. 17 to 20 illustrate operations of attaching the first wall 23. In these drawings, the coupling mechanism 50 corresponding to the valve 4B is illustrated as a representative example. Further, the tank 3 is illustrated to be arranged while being deviated and the opening direction of the first recess 44 in the valve 4B is illustrated to be inclined from the front-rear direction (the X-direction). In addition, the valve 4B is in the closed state. In the coupling mechanism 50, the pressure of the elastic body 64 is applied to the first engaging portion 5 so that, as illustrated in FIG. 7, the second protrusion 541 is positioned at the front end of the groove 743 of the first seal 7 and come into contact with the regulation plate 75.

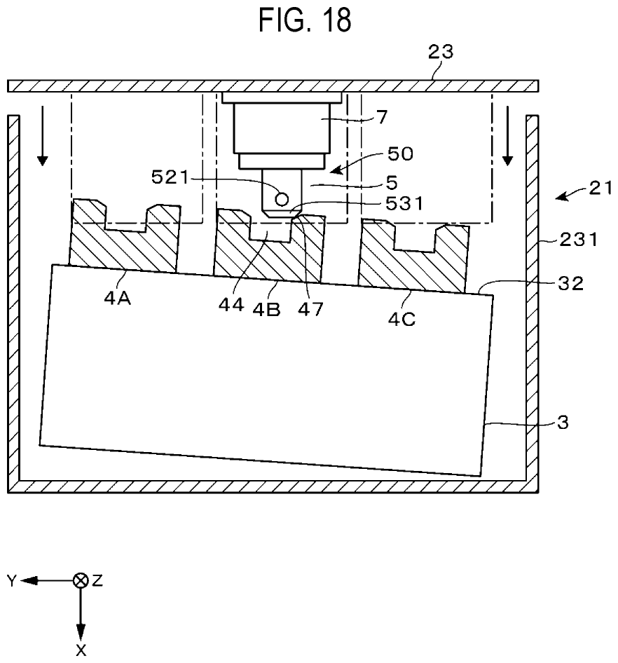

In this operation, first, the first wall 23 is brought closer to the opening of the first housing main body 231 (FIG. 17). Thereafter, due to the misalignment of the first recess 44, the inclined surface 531 of the entry portion 51 of the first engaging portion 5 is brought into contact with the opening edge 443 or the inclined surface 47 of the first recess 44 (FIG. 18). Since the entry portion 51 is swingable due to the elastic body 64, the first wall 23 is further close to the first housing main body 231 and the tip of the entry portion 51 enters the first recess 44 while the orientation thereof is changed. The tip of the entry portion 51 moves inward of the first recess 44 while bring into contact with the inner wall of the first recess 44. More specifically, the front portion (the first linear portion) 52 constituting the entry portion 51 is directed inward of the main portion 45 of the first recess 44, while the first protrusion 521 is directed inward of the sub-portion 451 of the first recess 44.

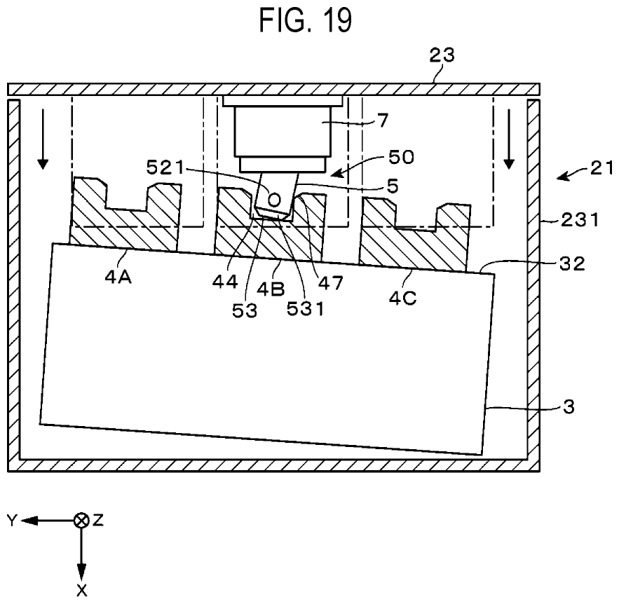

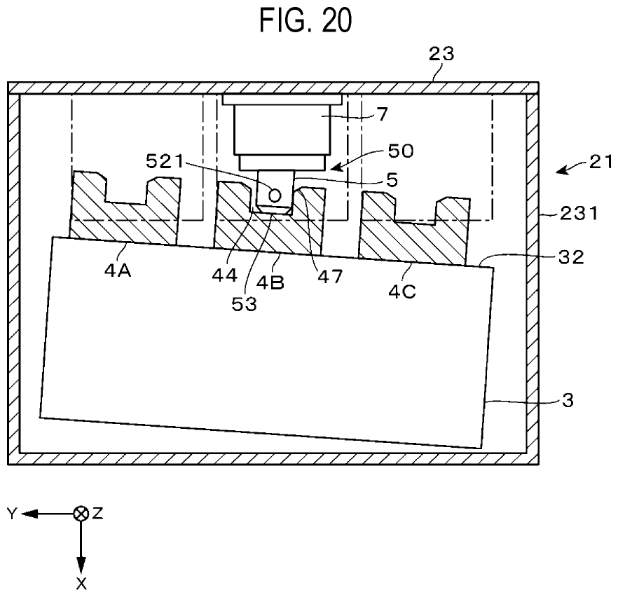

Further, the tip 53 of the entry portion 51 is brought into contact with the bottom surface 441 of the first recess 44 (FIG. 19), and consequently is brought into close contact with the bottom surface 441 of the first recess 44. Further, as the first wall 23 is close to the first housing main body 231, the first engaging portion 5 is press-fitted inward of the second recess 74 of the first seal 7. As a result, the state illustrated in FIG. 5 where the second protrusion 541 is spaced apart from the regulation plate 75 is obtained. Meanwhile, the first wall 23 is brought into contact with the first housing main body 231 (FIG. 20).

As described above, since the first engaging portion 5 is press-fitted inward of the first seal 7, the first seal 7 is biased toward the first wall 23 by the spring constituting the elastic body 64. Thus, the sealing surface 73 of the first seal 7 is pressurized against the surface 631 at the tip of the annular portion 63 of the outer frame 6 by the biasing force of the elastic body 64 so that the sealing surface 73 and the surface 631 are brought into surface-contact with each other. As a result, the first opening 230 is sealed.

Here, although only the valve 4B is illustrated, the first engaging portion 5 of the coupling mechanism 50 enters each of the three valves 4A to 4C until the tip 53 of the first engaging portion 5 is brought into contact with the bottom surface 441 of the first recess 44. In this state, the first wall 23 is screwed to the first housing main body 231 to form the first housing 21.

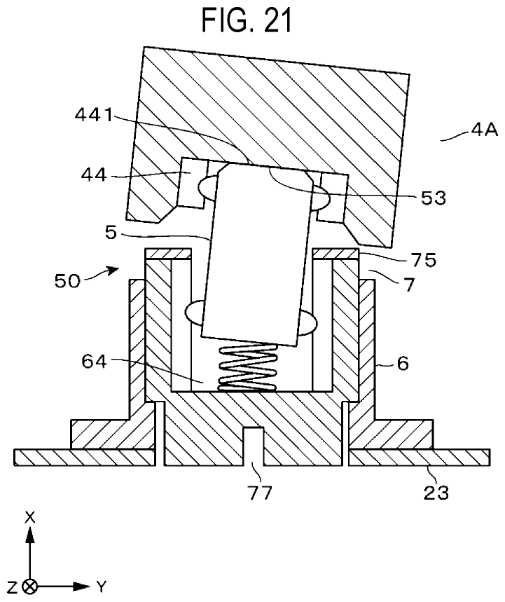

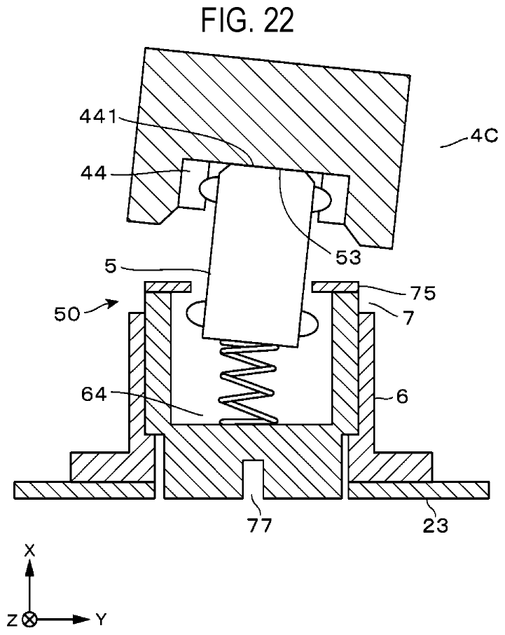

However, as illustrated in FIG. 16, when the tank 3 is arranged while being misaligned, a distance between the first recess 44 and the first wall 23 varies among the three valves 4A to 4C. FIG. 21 illustrates the valve 4A which is closest to the first wall 23. FIG. 22 illustrates the valve 4C which is farthest from the first wall 23.

Even in this case, since the first engaging portion 5 may swing relative to the first seal 7 and may also move in the front-rear direction, the first engaging portion 5 may enter the first recess 44 according to a positional relationship with the first recess 44. Further, the tip 53 of the first engaging portion 5 is brought into contact with the bottom surface 441 of the first recess 44 while an angle at which the tip 53 enters the first recess 44 or an amount of protrusion of the tip 53 from the first seal 7 is changed.

In this way, the coupling mechanism 50 equipped with the elastic body 64 is provided. Thus, even if the tank 3 is misaligned, the first engaging portion 5 may be engaged with the rotator 43 of the valve 4, which makes it possible to seal the first opening 230 by the first seal 7.

As described above, after the first housing 21 is formed, the second wall 24 is screwed to the second housing main body 241 of the second housing 22 which surrounds the first housing 21 to form the second housing 22. In this way, the gas box 2 is assembled.

Further, when opening the valve 4 in the closed state as illustrated in FIG. 5, the operator inserts the hex wrench 65 into the second housing 22 from the outside of the second housing 22 via the second seal 28 at the third opening 240 of the second wall 24. Subsequently, the tip of the hex wrench 65 is inserted into the recess 77 of the first seal 7 of the coupling mechanism 50. At this time, as illustrated in FIG. 14, the first region 81 of the display 8 overlaps the window 29 so that the text “CLOSE” is displayed. In addition, in FIG. 14, there is illustrated a state in which the opening and closing of the valve 4 is locked by the padlock 85. The padlock 85 needs to be separated before opening the valve 4.

Further, the operator turns the hex wrench 65 counterclockwise as viewed in the front side to apply the torque to the first seal 7 from the outside of the second housing 22 and rotate the first seal 7. With the rotation of the first seal 7, the side surface of the groove 743 of the first seal 7 pressurizes the second protrusion 541 formed on the columnar member 59 of the first engaging portion 5 so that the first engaging portion 5 is rotated around the central axis of the columnar member 59. As the first engaging portion 5 rotates, the first protrusion 521 of the first engaging portion 5 pressurizes the side surface of the sub-portion 451 of the first recess 44 in the rotator 43 of the valve 4 so that the rotator 43 is rotated in the same direction as the direction in which the hex wrench 65 is turned.

As described above, the torque applied to the first seal 7 is transmitted to the rotator 43 via the first engaging portion 5. With the rotation of the rotator 43, the ball 42 of the valve 4 rotates 90 degrees around the center thereof so that a state in which the flow path 31 is opened (that is, the valve 4 is opened) as illustrated in FIG. 6 is obtained. In this drawing, there is illustrated a state in which the second protrusion 541 of the first engaging portion 5 is pressurized by the side surface of the groove 743 of the first seal 7, and the first protrusion 521 of the first engaging portion 5 pressurizes the side surface of the sub-portion 451 of the first recess 44 of the valve 4.

As described above, as the first seal 7 rotates, the display 8 also rotates. When the flow path 31 is opened, as illustrated in FIG. 13, the second region 82 of the display 8 overlaps the window 29 so that the text “OPEN” is displayed.

As described above, each valve 4 is opened by turning the hex wrench 65 in the outside of the second housing 22. Further, when processing the wafer W, the liquid 30 is supplied to and stored in the tank 3. In a state in which the stored liquid 30 is heated by the heater 33, the carrier gas is supplied into the tank 3 where the liquid 30 is vaporized. In addition the carrier gas, a first gas generated by the vaporization is supplied into the processing container 11 via the flow path 31. Thus, the wafer W is processed using the first gas in the interior of the processing container 11.

On the other hand, when closing the valve 4, the operator turns the hex wrench 65 in a direction opposite that when opening the valve 4 to rotate the first seal 7. As a result, the torque is transmitted to the rotator 43 via the first engaging portion 5 in the opposite direction to that when opening the valve 4, so that the valve 4 is closed. As the first seal 7 rotates, the text “CLOSE” is again displayed on the display 8 via the window 29.

As described above, during the first seal 7 is being rotated to open or close the valve 4, the sealing surface 73 of the first seal 7 is continuously pressurized by the surface 631 of the outer frame 6 provided on the first wall 23 of the first housing 21 through the elastic body 64. This ensures the state in which the first opening 230 of the first wall 23 is sealed.

In addition, although in the above, the first wall 23 has been described to be attached while the tank 3 is misaligned, the first wall 23 may be attached in a similar manner even when the tank 3 is not misaligned. In this case, the first engaging portion 5 of the coupling mechanism 50 may enter the first recess 44 of the valve 4 without interfering with the opening edge 443 or the inclined surface 47 of the first recess 44. This makes it possible to implement the engagement between the first engaging portion 5 and the first recess 44, and the sealing of the first opening 230 of the first wall 23.

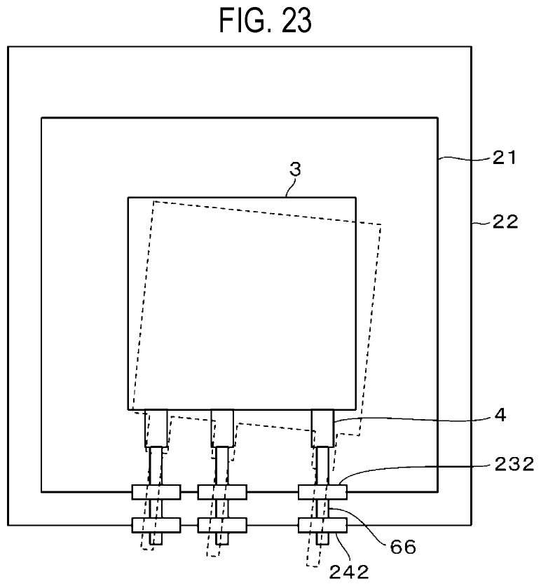

Next, a configuration of Comparative Example in which the coupling mechanism 50 of the present disclosure is not provided will be considered with reference to a schematic view of FIG. 23. In this case, for example, as illustrated by solid lines in FIG. 23, seals 232 and 242, which are made of, for example, grommet like the second seal 28, are provided at the openings of the first housing 21 and the second housing 22, respectively. Further, for example, a configuration may be considered in which a bar-like coupling member 66 is inserted into the second housing 22 from the outside of the second housing 22, and a tip of the coupling member 66 is rotated while being engaged with the valve 4 to open or close the valve 4.

With this configuration, when the tank 3 is arranged at a preset position as illustrated by solid lines in FIG. 23, the valve 4 may be rotated by the coupling member 66. However, in a case in which the tank 3 is arranged to be misaligned as illustrated by dashed lines in FIG. 23, when the coupling member 66 is engaged with the valve 4, it may move to a position deviated from the centers of the seals 232 and 242. As a result, among a plurality of sealing pieces forming the same seal out of the seals 232 and 242, some of the sealing pieces may be bent due to interference with the coupling member 66, while the others may be in a state of being spaced apart from the coupling member 66 without being bent. In other words, since a gap may be formed between the others among the plurality of sealing pieces and the coupling member 66, the airtightness of each of the first housing 21 and the second housing 22 may not be sufficiently secured. Further, when the tank 3 is significantly misaligned, the engagement between the coupling member 66 and the valve 41 may not be implemented.

The following returns to describing the first embodiment. According to the first embodiment, the torque may be applied to the rotator 43 of the valve 4 via the coupling mechanism 50 from the outside of the first housing 21. Meanwhile, in the coupling mechanism 50, the first seal 7 is biased toward the first wall 23 of the first housing 21 by the elastic body 64, the coupling mechanism 50 is exposed to the outside of the first housing 21 due to the application of the torque, and the first opening 230 formed in the first wall 23 is sealed. Accordingly, compared to Comparative Example, it is possible to secure the airtightness of the first housing 21 at a relatively high level and perform the opening or closing of the valve 4 from the outside of the first housing 21 while securing the safety.

In addition, as described above, when the tank 3 is misaligned inside the first housing 21 during the installation of the pipes inside the first housing 21, the positional relationship between the tank 3 and the first wall 23 of the first housing 21 may vary from a preset positional relationship. On the other hand, the positional relationship between the first wall 23 and the second wall 24 of the second housing 22 is not affected by the installation of the pipes and therefore is less likely to vary from a preset positional relationship. Accordingly, in the coupling mechanism 50 attached to the first wall 23, a positional relationship between the recess 77 into which the hex wrench 65 is inserted, and the second seal 28 into which the hex wrench 65 is inserted in the second wall 24, is less likely to vary from a preset positional relationship.

Therefore, when the hex wrench 65 is inserted into the recess 77 via the second seal 28, the hex wrench 65 may pass through the center of the second seal 28. Thus, the sealing pieces 281 are bent equally or approximately equally, and are in close contact with the hex wrench 65. Even if the tank 3 is arranged to be misaligned, it is possible to prevent a situation in which the sealing pieces are spaced apart from the jig (the hex wrench 65) to form the gap as described in Comparative Example.

Further, the first engaging portion 5 is provided on the first seal 7 via the elastic body 64 and is configured to be swingable and movable in the front-rear direction. Therefore, even if the tank 3 is arranged to be deviated from the preset position, the coupling mechanism 50 may absorb a fluctuation caused by the misalignment to secure airtightness. Further, it is possible to perform the opening and closing of the valve 4 from the outside of the first housing 21. In addition, a situation in which the tank 3 is arranged while being positioned inside the first housing 21 may be considered. In a case in which the position of the tank 3 is considered preferentially, when the pipe is accommodated in the first housing 21, the pipe may be bent excessively. This may impose a load on the pipe, which causes damages to the pipe or liquid leakage. This is not undesirable.

As described above, the gas box 2 has a double structure with the first housing 21 and the second housing 22 provided outside the first housing 21. The valves 4 (4A to 4C) are provided to manually open or close each of the flow paths 31, 35 and 36 provided in the interior of the first housing 21. The opening or closing of the valve 4 may be performed from the outside of the first housing 21. Further, the display 8 configured to rotate together with the coupling mechanism 50 is provided. By the display 8, whether the valve 4 is in the closed state or the open state may be visually checked. When the valve 4 is in the closed state, the locking is implemented to prevent the rotation of the valve 4. Therefore, it is possible to manually open or close the valve 4 from the outside of the gas box 2 and cope with Lockout/Tagout (LOTO), which improves safety during the inspection and maintenance of the gas box 2.

### Second Embodiment

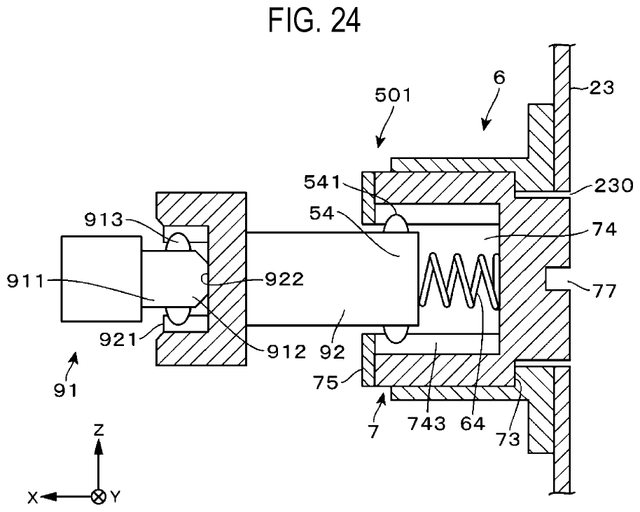

The gas box of the present disclosure may be configured such that a coupling mechanism 501 has a first recess 921 and a rotator 91 of the valve 4 has an entry portion 911 that enters the first recess 921. This configuration example will be described with reference to FIG. 24. As illustrated in FIG. 24, for example, the entry portion 911 of a cylindrical shape is provided on a base side (the rear side in the X-direction) of the rotator 91 of the valve 4. The entry portion 911 has a first linear portion 912 that extends in a linear direction (the X-direction) and a first protrusion 913. The first protrusion 913 is formed to protrude in a direction intersecting an extension direction (X-direction) of the first linear portion 912.

Further, the first recess 921 is formed in the tip (the front side in the X-direction) of a first engaging portion 92 so as to open toward the front side. When the rotator 91 and the first engaging portion 92 are engaged with each other, the tip of the entry portion 911 is brought into contact with a bottom surface 922 of the first recess 921. Other components, such as the first seal 7 and the elastic body 64 included in the coupling mechanism 501 and the rear portion (the second linear portion) 54 or the second protrusion 541 provided on the base side of the first engaging portion 92, are the same as those in the first embodiment, and therefore the same reference numerals will be given to the same components and descriptions thereof will be omitted.

In this embodiment as well, the entry portion 911 of the rotator 91 enters the first recess 921 formed in the first engaging portion 92 so that the rotator 91 is engaged with the first engaging portion 92. Further, torque is applied to the rotator 91 via the coupling mechanism 501 from the outside of the first housing 21 so that the rotator 91 is rotated to open or close the valve 4 while maintaining the airtightness of the first housing 21.

### Third Embodiment

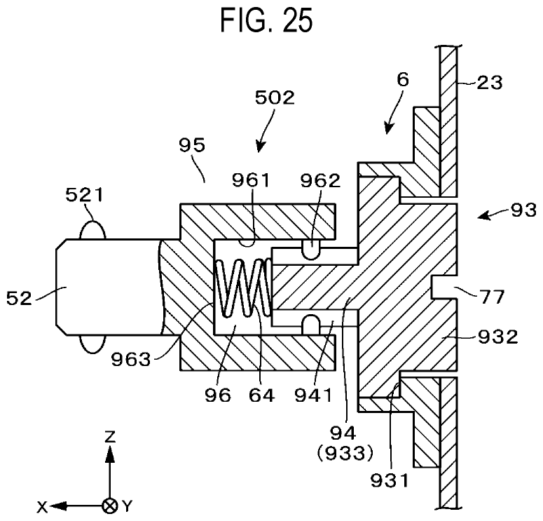

Further, a coupling mechanism 502 of the gas box of the present disclosure may be configured such that a first engaging portion 95 has a second recess 96, and a first seal 93 has a second linear portion 94 that enters the second recess 96. This configuration example will be described with reference to FIG. 25. As illustrated in FIG. 25, for example, the second recess 96 is formed in the base side (the rear side in the X-direction) of the first engaging portion 95 to be opened toward the first wall 23.

Further, the first seal 93 is configured to have a columnar body 933 sized to enter the second recess 96. The columnar body 933 protrudes in the front side from a columnar member 932 forming a sealing surface 931. The second linear portion 94 is formed by the columnar body 933.

Further, in this example, a second protrusion 962 is provided on a side surface 961 of the second recess 96. A groove 941 is formed in a circumferential surface of the second linear portion 94. The groove 941 is formed along an extension direction (the X-direction) of the second linear portion 94. The second protrusion 962 is configured to enter the groove 941. Further, the elastic body 64 is provided between a bottom surface 963 of the second recess 96 and the tip of the second linear portion 94. Other components, such as the first linear portion 52 and the first protrusion 521 provided on the tip side of the first engaging portion 95, are the same as those in the first embodiment, and therefore the same reference numerals will be given to the same components and descriptions thereof will be omitted.

As described above, the coupling mechanism may be configured in various other ways as long as the second protrusion is formed on one of the side surface of the second recess and the circumferential surface of the second linear portion, and the groove to which the second protrusion enters is formed on the other. Even with this configuration, the first engaging portion 95 enters the first recess 44 of the rotator 43 so that the first engaging portion 95 is engaged with the rotator 43. Further, torque may be applied to the rotator 43 via the coupling mechanism 502 from the outside of the first housing 21 so that the rotator 43 is rotated to open or close the valve 4. In this case, since the elastic body 64 is provided between the first seal 93 and the first engaging portion 95, the first seal 93 is biased from the first engaging portion 95 toward the first wall 23 by virtue of the biasing force of the elastic body 64. This secures the airtightness of the first housing 21.

In the present disclosure described above, the gas supplied from the gas box 2 to the processing container 11 is not limited to a processing gas used for the substrate processing, but may include a gas which is supplied during the substrate processing but is not directly involved in the substrate processing. In addition to the carrier gas described above, examples of the gas which is not directly involved in the substrate processing may include a purge gas for purging the interior of the processing container 11, an inert gas supplied into the processing container 11 during annealing of the wafer W, and the like.

Further, the gas supplied from the gas box 2 to the processing container 11 is not limited to the gases supplied to the processing container 11 in which the wafer W is accommodated. Specifically, a cleaning gas may be supplied from the gas box 2 to the processing container 11 in which the wafer W is not stored, to clean the processing container 11.

Further, a fluid, which is a raw material for the gas to be supplied to the processing container 11, may include a gas, a gas generated by vaporizing a liquid, a gas generated by heating and sublimating, by the heater 33, a material such as tungsten chloride (WCl₆) that is solid at normal temperature and stored in the tank 3, or the like.

Further, in the example described above, the first wall 23 and the second wall 24 of the first housing 21 and the second housing 22 are configured as detachable front walls. However, the first wall 23 and the second wall 24 may be configured to be opened or closed in a state in which one sides of the first wall 23 and the second wall 24 is supported by the first housing main body 231 and the second housing main body 241 with hinges, respectively. Further, the gas box 2 in this example has the double structure in which the first housing 21 and the second housing 22 surrounding the first housing 21 are provided. However, the present disclosure is not limited to thereto and the second housing 22 may be omitted.

Further, in the present disclosure, the processing container 11 is not limited to have a single-wafer configuration, and may have a configuration in which a plurality of wafers W is processed inside a single processing container. Further, the tank 3 may not be provided in the first housing 21. A flow path through which the fluid as a gas raw material flows may be provided in the first housing 21.

Further, the valve 4 provided in the present disclosure is not limited to the ball valve. A valve having a structure capable of opening or closing the flow path 31 with the rotation of the rotator 43, such as a butterfly valve, may be used as the valve 4.

Further, in this example, the valves 4A to 4C of the present disclosure are provided in the first flow path 35, the second flow path 36, and the third flow path 31, respectively. However, only one of the plurality of valves may be provided in, for example, the third flow path 31. Further, separately from the valves 4A to 4C of the present disclosure which are manually opened and closed, an air-operated valve, which is automatically opened or closed to control the supply and cutoff of a liquid or gas, may be provided in each of the first flow path 35, the second flow path 36, and the third flow path 31.

Further, the elastic body 64 provided in the coupling mechanism 50 is not limited to the spring, and may be a sponge or resin exhibiting a restoring force.

Further, in the above example, the second engaging portion 77, which is provided on the rear surface of the first seal 7 and is exposed to the first opening 230 of the first wall 23, has been described as the recess, but may be appropriately modified according to a jig used for rotating the first seal 7. For example, when the jig is a socket wrench, a protrusion may be used instead of the recess.

Further, in the first embodiment, when the first recess 44 of the valve 4 and the entry portion 51 of the coupling mechanism 50 are configured to have a rectangular shape, one of the first recess 44 and the entry portion 51 may rotate the other. In other words, the entry portion 51 may be formed by a rectangular columnar member instead of the columnar member 59 to be engaged with the first recess of a rectangular shape. In this case, there is no need to form the first protrusion on the entry portion and the sub-portion in the first recess.

Further, when the rectangular columnar member is used instead of the columnar member 59, the second recess 74 of the first seal 7 may have a rectangular shape, which makes it possible to rotate the rectangular columnar member with the rotation of the first seal 7. In other words, like the first protrusion 521, the second protrusion 541 may not be essential. In addition, a configuration in which the rectangular columnar member is engaged with the rectangular recess to transmit the torque may be applied to the second and third embodiments. Thus, the first and second protrusions 521 and 541 or equivalent protrusions may be omitted.

However, it is desirable to include the first and second protrusions 521 and 541 to ensure more reliable the positioning and the transmission of the torque. Further, in the case in which the rectangular columnar member is accommodated in the second recess of a rectangular shape to transmit the torque, it is difficult to increase a range of swing of the tip of the rectangular columnar member. Therefore, as described above, it is desirable to include the protrusions to more reliably ensure the transmission of the torque. In addition, the number of first and second protrusions 521 and 541 may be optional and is not limited to two for each protrusion.

Further, in the first embodiment, the third recess 55 in which the elastic body 64 is accommodated, may be provided on the bottom surface 741 of the second recess 74 of the first seal 7, rather than being provided on the columnar member 59. However, when a thickness of the bottom portion of the first seal 7 forming the third recess 55 is relatively increased such that the third recess 55 has a sufficient depth to prevent the elastic body 64 from being separated from the third recess 55, the coupling mechanism 50 may be bulky. Therefore, it is desirable to provide the third recess 55 in the columnar member 59 as illustrated in the first embodiment.

Further, the display 8, which also serves as the deviation preventer, may not be formed in the disk shape and may have any shape as long as it may prevent the coupling mechanism 50 from being separated from the first opening 230.

Further, the different pieces of visual information provided on the display may include text information as in the above-described embodiment, or may include information relating to symbols, patterns, or colors. Further, the visual information may be provided on one of the first and second regions, while the other region may remain blank. This is because they may still be distinguished from each other even in this case.

Further, the visual information may include shape information. As a specific example of the shape information, instead of indicating the text “OPEN” or “CLOSE” on the display, for example, concave and convex portions may be formed to exhibit a difference in shape between the first region and the second region so that the operator may visually recognize such a shape difference. In this case, the concave and convex portions may be formed in one of the first region and the second region, and the other region may be a flat surface.

Further, in a case in which the window, through which the visual information is displayed, does not have a structure where the locking is implemented with the padlock, the clamp 83 may not be inserted into the through-hole. Thus, the window is not limited to an opening. The window may be a transparent wall made of quartz or the like as long as the operator can visually check the display 8 inside the second housing 22 from the outside.

In the above, the wafer has been described as an example of the substrate. However, the substrate to be processed in the processing container 11 may be a substrate for semiconductor manufacture. In addition to the wafer, examples of the substrate for semiconductor manufacture may include a substrate for manufacturing a flat panel display, a substrate for manufacturing an exposure mask used in photolithography, a dummy substrate used to perform a test or set processing parameters in a substrate processing apparatus, and the like.

According to the present disclosure in some embodiments, in a gas box in which a flow path which is opened or closed by rotating a valve is provided inside a first housing, it is possible to open or close the flow path while maintaining airtightness of the first housing.

It should be noted that the embodiments disclosed herein are exemplary in all respects and are not restrictive. The above-described embodiments may be omitted, replaced or modified in various forms without departing from the scope and spirit of the appended claims.

What is claimed is:

1. A gas box comprising:
a first housing having a flow path for a fluid provided therein;
a valve equipped with a rotator and configured to open or close the flow path with rotation of the rotator;
a first opening provided in a first wall of the first housing;
a coupling mechanism including an elastic body and a first engaging portion engaged with the rotator to connect the rotator and the first wall, the coupling mechanism being provided to face the first opening so as to rotate together with the rotator by torque applied from outside the first housing; and
a first seal included in the coupling mechanism and configured to be biased from the first engaging portion toward the first wall by the elastic body to seal the first opening.

2. The gas box of claim 1, further comprising:
an outer frame provided on the first wall inside the first housing and configured to surround the first seal so that the first seal is capable of rotating inside the outer frame;
an annular portion formed on the outer frame to protrude inward of the outer frame, the annular portion forming the first opening together with a through-hole provided in the first wall; and
a sealing surface provided on the first seal to come into contact with the annular portion and to seal the first opening.

3. The gas box of claim 1, further comprising:
a second housing configured to surround the first housing and having a second wall provided to face the first wall;
a window provided in the second wall and through which an interior of the second housing is visible from an outside of the second housing; and
a display having a first region and a second region with different pieces of visual information, and configured to rotate while being connected to the coupling mechanism so that a region facing the window switches between the first region and the second region according to an open state or a closed state of the flow path so as to indicate the open state or the closed state of the flow path outward of the second housing.

4. The gas box of claim 3, wherein the display is provided to not only face the first opening but also extend beyond the first opening, and serves as a deviation preventer configured to prevent the coupling mechanism from detaching from the first wall.

5. The gas box of claim 4, wherein the window is a second opening provided in the second wall,
wherein the gas box further comprises:
a first through-hole forming member having a first through-hole located outside the second housing, the first through-hole forming member being inserted into the second opening and connected to the coupling mechanism so that the first through-hole moves outside the second housing as the coupling mechanism rotates; and
a second through-hole forming member provided on the second wall outside the second housing and having a second through-hole,
wherein the first through-hole is open in an opening direction of the second through-hole in a first state in which the flow path is closed and the first region faces the window, and
wherein the first through-hole is not open in the opening direction of the second through-hole in a second state in which the flow path is opened and the second region faces the window.

6. The gas box of claim 1, further comprising:
a second engaging portion provided on the first seal to be exposed to the first opening so that the second engaging portion is engaged with a jig configured to apply the torque;
a second housing configured to surround the first housing and having a second wall provided to face the first wall;
a third opening provided in the second wall to face the first opening so that the jig enters the second housing from an outside of the second housing;
a second seal made of an elastic body to block and seal the third opening; and
a plurality of sealing pieces provided along a periphery of the third opening to form the second seal, wherein tips of the plurality of sealing pieces are configured to come into contact with each other at a center of the third opening when the jig does not enter the third opening, and to be spaced apart from each other to face the first wall when the jig enters the third opening.

7. The gas box of claim 1, wherein one of the rotator and the first engaging portion has a first recess, and the other of the rotator and the first engaging portion has an entry portion configured to enter the first recess and come into contact with a bottom surface of the first recess.

8. The gas box of claim 7, wherein a region from an opening edge of a side surface of the first recess toward the bottom surface forms an inclined surface which is inclined with respect to an opening direction of the first recess, so that an opening area of the first recess increases toward the opening edge from the bottom surface.

9. The gas box of claim 7, wherein the entry portion includes a first linear portion extending in a linear direction and a first protrusion protruding from the first linear portion in a direction intersecting an extension direction of the first linear portion, and
wherein the first recess includes a main portion to which the first linear portion enters, and a sub-portion formed to protrude from the main portion and to which the first protrusion enters.

10. The gas box of claim 1, wherein, in the first engaging portion in a state of not being engaged with the rotator, a tip side for engagement with the rotator is slidable relative to a base side connected to the first seal via the elastic body.

11. The gas box of claim 1, wherein one of the first engaging portion and the first seal includes a second recess configured to accommodate a second linear portion provided on the other of the first engaging portion and the first seal,
wherein the second linear portion extends linearly along an opening direction of the second recess, and
wherein the elastic body is provided between a bottom surface of the second recess and the second linear portion.

12. The gas box of claim 11, wherein a groove is provided in one of a side surface of the second recess and a circumferential side of the second linear portion, and a second protrusion is provided on the other of the side surface of the second recess and the circumferential side of the second linear portion,
wherein the groove is formed along the opening direction of the second recess when formed in the second recess and is formed along an extension direction of the second linear portion when formed in the second linear portion, and
wherein the second protrusion enters the groove.

13. The gas box of claim 12, wherein the first seal includes the second recess, and wherein the groove is formed in the second recess.

14. The gas box of claim 13, wherein the second linear portion includes a third recess having a bottom surface facing the bottom surface of the second recess, and
wherein the elastic body is provided between the bottom surface of the second recess and the bottom surface of the third recess.

15. The gas box of claim 1, wherein a tank is provided inside the first housing and includes a heater configured to heat and vaporize a liquid stored in the tank,
wherein the flow path includes:
a first flow path through which the liquid is supplied to the tank;
a second flow path for supplying a carrier gas for a first gas generated by heating the liquid to the tank; and
a third flow path for supplying the carrier gas and the first gas outward of the tank, and
wherein the valve, the first opening, and the coupling mechanism are provided for each of the first flow path, the second flow path, and the third flow path.

16. The gas box of claim 1, further comprising a second housing configured to surround the first housing and having a second wall facing the first wall,
wherein the first housing is connected to a supply path for supplying an inert gas and a first exhaust path for exhausting the first housing, and
wherein the second housing is connected to a second exhaust path for exhausting the first housing.

17. A semiconductor manufacturing apparatus comprising:
a processing container configured to accommodate and process a substrate; and
a gas box
wherein the gas box includes:
a first housing having a flow path provided therein, wherein a fluid which becomes a gas to be supplied into the processing container flows through the flow path;
a valve equipped with a rotator and configured to open or close the flow path with rotation of the rotator;
a first opening provided in a first wall of the first housing;
a coupling mechanism including an elastic body and a first engaging portion engaged with the rotator to connect the rotator and the first wall, the coupling mechanism being provided to face the first opening so as to rotate together with the rotator by torque applied from outside the first housing; and
a first seal included in the coupling mechanism and configured to be biased from the first engaging portion toward the first wall by the elastic body to seal the first opening.
